(19) United States
(12) Patent Application Publication
(10) Pub. No.: US 2016/0202520 A1
(43) Pub. Date: Jul. 14, 2016

(54) DISPLAY DEVICE AND RELATED MANUFACTURING METHOD

(71) Applicant: Samsung Display Co., Ltd., Yongin-si (KR)

(72) Inventors: Pil Soon HONG, Gwangmyeong-si (KR); Gwui-Hyun PARK, Hwaseong-si (KR); Jin Ho JU, Seoul (KR)

(21) Appl. No.: 14/872,961

(22) Filed: Oct. 1, 2015

(30) Foreign Application Priority Data
Jan. 8, 2015 (KR) 10-2015-0002973

(51) Int. Cl. G02F 1/1368; G02F 1/1362; G02F 1/1339; G02F 1/1335; H01L 27/12; G02F 1/1333

(52) U.S. Cl. CPC G02F 1/1368; H01L 27/1288; G02F 1/133345; G02F 1/13394; G02F 1/133512; G02F 1/136286

(57) ABSTRACT

A display device may include the following elements: a first transistor including a gate electrode, a source electrode, and drain electrode; a gate line electrically connected to the gate electrode; a data line electrically connected to the source electrode; a common electrode; a passivation layer overlapping the common electrode; a first pixel electrode electrically connected to the drain electrode and positioned between the common electrode and the passivation layer; a first liquid crystal layer, which is positioned between the common electrode and the first pixel electrode; a second transistor electrically connected to the gate line; a second pixel electrode electrically connected to the second transistor; a second liquid crystal layer positioned between the common electrode and the second pixel electrode; and a supporting member positioned between the common electrode and the passivation layer and positioned between the first liquid crystal layer and the second liquid crystal layer.

### CROSS-REFERENCE TO RELATED APPLICATION

This application claims priority to and the benefit of Korean Patent Application No. 10-2015-0002973 filed in the Korean Intellectual Property Office on Jan. 8, 2015; the entire contents of the Korean Patent Application are incorporated herein by reference.

### BACKGROUND

(a) Field

The present invention is relate to a display device, e.g., a liquid crystal display, and is related to a method for manufacturing the display device.

(b) Description of Related Art

Display devices may be used for computer monitors, televisions, mobile phones, etc. Display devices may include cathode ray tube display devices, liquid crystal displays, plasma display devices, etc.

A typical liquid crystal display device may include two panels with field generating electrodes (such as a pixel electrode and a common electrode) and may include a liquid crystal layer interposed between the two panels. The liquid crystal display device may generate an electric field in the liquid crystal layer by applying a voltage to the field generating electrodes to control orientations of liquid crystal molecules of the liquid crystal layer through for and controlling transmission of light through the liquid crystal layer, thereby displaying images. Two substrates may be used for implementing the two panels. The two substrates may undesirably contribute to the thickness, the weight, the manufacturing cost, and/or the manufacturing time of the liquid crystal display device.

The above information disclosed in this Background section is for enhancement of understanding of the background of the invention. The Background section may contain information that does not form the prior art that is already known in this country to a person of ordinary skill in the art.

### SUMMARY

Embodiments of the present invention may be related to a display device (e.g., a liquid crystal display device) that may include only one major structural substrate and may have a substantially uniform cell gap. Embodiments of the present invention may be related to a method for manufacturing the display device. Embodiments of the present invention may advantageously minimize the weight, thickness, costs, and a manufacturing time associated with the display device.

An embodiment of the present invention may be related to a display device. The display device may include the following elements: a first transistor, which may overlap an substrate (e.g., an insulating substrate) and may include a gate electrode, a source electrode, and drain electrode; a gate line, which may be electrically connected to the gate electrode; a data line, which may be electrically connected to the source electrode; a common electrode; a passivation layer, which may overlap the common electrode; a first pixel electrode, which may be electrically connected to the drain electrode and may be positioned between the common electrode and the passivation layer; a first liquid crystal layer, which may be positioned between the common electrode and the first pixel electrode; a second transistor, which may be electrically connected to the gate line; a second pixel electrode, which may be electrically connected to the second transistor; a second liquid crystal layer, which may be positioned between the common electrode and the second pixel electrode; and a supporting member, which may be positioned between the common electrode and the passivation layer and may be positioned between the first liquid crystal layer and the second liquid crystal layer.

The supporting member may overlap the data line.

The display device may include a light blocking member, which may be positioned between the supporting member and the data line.

The supporting member may directly contact a first side of the passivation layer. The first pixel electrode may directly contact the first side of the passivation layer.

A first portion of the common electrode may be positioned between the inorganic layer and the liquid crystal layer. A second portion of the common electrode may be positioned between the inorganic layer and the supporting member.

The supporting member may be formed of a positive photoresist material.

The display device may include an inorganic, which may directly contact a first side of the common electrode. The supporting member may directly contact a second side of the common electrode. A maximum thickness of the inorganic layer in a direction perpendicular to the common electrode may be 2 μm or less.

A first side of the supporting member may directly contact the passivation layer. A second side of the supporting member may directly contact the common electrode. The first side of the supporting member may be narrower (and/or smaller) than the second side of the supporting member.

The display device may include an alignment, which may directly contact each of the common electrode, the supporting member, and the first liquid crystal layer and may be configured for orienting liquid crystal molecules in the first liquid crystal layer.

A portion of the supporting member may directly contact the common electrode and may be positioned between the common electrode and the first pixel electrode in a direction perpendicular to the common electrode. The portion of the supporting member may have an acute angle in a cross-sectional view of the display device.

An embodiment of the present invention may be related to a display device. The display device may include the following elements: a transistor, which may overlap a substrate (e.g., an insulating substrate) and may include a gate electrode, a source electrode, and drain electrode; a gate line, which may be electrically connected to the gate electrode; a data line, which may be electrically connected to the source electrode; a common electrode; a passivation layer, which may overlap the common electrode; a pixel electrode, which may be electrically connected to the drain electrode and may be positioned between the common electrode and the passivation layer; a liquid crystal layer, which may be positioned between the common electrode and the pixel electrode; and a supporting member, which may be formed of a positive photoresist material and may be positioned between the common electrode and the passivation layer.

The display device may include a light blocking member, which may overlap the supporting member in a direction perpendicular to the common electrode. The passivation layer may directly contact each of the supporting member and the light blocking member.

A first side of the supporting member may be positioned between the light blocking member and a second side of the supporting member. The first side of the supporting member may be narrower than at least one of the light blocking member and the second side of the supporting member in a direction parallel to the gate line. The light blocking member may be wider than the first side of the supporting member and may be narrower than the second side of the supporting member in the direction parallel to the gate line.

An embodiment of the present invention may be related to a method for manufacturing a display device. The method may include the following steps: forming a thin film transistor that overlaps a substrate (e.g., an insulating substrate); forming a pixel electrode that may be connected to the thin film transistor; providing a positive photoresist layer that covers the pixel electrode; exposing a first portion of the positive photoresist layer to light when blocking a second portion of the positive photoresist layer from the light; providing a conductor layer on the positive photoresist layer; providing an inorganic layer that has an opening on the conductor layer; etching the conductor layer through the opening to form a common electrode that has a hole; providing a developer through the opening and the hole for removing the first portion of the positive photoresist layer to form a cavity, wherein the second portion of the photoresist layer may remain as a supporting member; providing a liquid crystal material through the opening and the hole into the cavity to form a liquid crystal layer; and providing an overcoat that covers the inorganic layer and seals the opening.

The method may include providing a passivation layer before forming the pixel electrode. The pixel electrodes may be formed on the passivation layer. The supporting member may directly contact each of the common electrode and the passivation layer.

The method may include providing a light blocking member. The supporting member may overlap the light blocking member in a direction perpendicular to the common electrode. A first side of the supporting member may be positioned between the light blocking member and a second side of the supporting member. The first side of the supporting member may be narrower than at least one of the light blocking member and the second side of the supporting member.

The first side of the supporting member may be narrower than the light blocking member in a direction parallel to the common electrode. The light blocking member may be narrower than the second side of the supporting member in the direction parallel to the gate line.

A maximum thickness of the inorganic layer in a direction perpendicular to the common electrode may be 2 μm or less.

The supporting member may have a first side and a second side. The second side may directly contact the common electrode, may be parallel to the first side, and may be wider than the first side in a direction parallel to the gate line.

The method may include providing an alignment material through the opening and the hole into the cavity to form an alignment layer before forming the liquid crystal layer. The alignment layer may directly contact each of the common electrode and the supporting member.

An embodiment of the present invention may be a liquid crystal display device. The liquid crystal display device may include the following elements: an insulation substrate; a gate line and a data line positioned on the insulation substrate and crossing each other in a plan view of the liquid crystal display device; a thin film transistor electrically connected with the gate line and the data line; a light blocking member positioned on the thin film transistor; a color filter abutting the light blocking member; a pixel electrode positioned on the color filter and electrically connected to the thin film transistor; a supporting member partially overlapping the pixel electrode in a direction perpendicular to the substrate; a common electrode positioned on the supporting member; a liquid crystal layer positioned between the pixel electrode and the common electrode and overlapping the supporting member in a direction parallel to the gate line; and an inorganic layer and an overcoat positioned on the common electrode.

The supporting member may extend parallel to the data line and may overlap the data line.

The supporting member may overlap the light blocking member.

The common electrode and the pixel electrode may be spaced from each other by at least the supporting member.

The common electrode and the inorganic layer may be substantially flat.

The supporting member may be formed of a positive photoresist material.

The thickness of the inorganic layer may be 2 μm or less.

A first side of the liquid crystal layer may be positioned between the color filter and a second side of the liquid crystal layer. The second side of the liquid crystal layer may be narrower than the color filter in a direction parallel to the gate line.

An embodiment of the present invention may be related to a method for manufacturing a liquid crystal display device. The method may include the following steps: forming a thin film transistor on an insulation substrate; forming a pixel electrode that is connected to the thin film transistor; forming a sacrificial layer on the pixel electrode, wherein the sacrificial layer may be formed of a positive photoresist material; irradiating light to a part of the sacrificial layer; providing a conductor layer on the sacrificial layer; forming an inorganic layer that has an opening on the conductor layer; etching the conductor layer through the opening of the inorganic layer to form a common electrode that has a hole; providing a developer through the opening and the hole for removing the part of the sacrificial layer to form a cavity; providing a liquid crystal material through the opening and the hole into the cavity to form a liquid crystal layer; and forming an overcoat that covers the inorganic layer and seals the opening and the hole.

After the part of the sacrificial layer has been removed, a remaining portion of the sacrificial layer may form a supporting member, which may support the common electrode.

A portion of the sacrificial layer to which the light is not irradiated may be insoluble to the developer. The part of the sacrificial layer to which the light is irradiated may be soluble to the developer.

The common electrode and the pixel electrode may be spaced apart from each other by at least the supporting member. The common electrode and the inorganic layer may be substantially flat.

The thickness of the inorganic layer may be 2 μm or less.

A cross section of the cavity that is parallel to a gate line of the liquid crystal display device may have a substantially trapezoid shape.

The manufacturing method may further include forming a color filter and a light blocking member which abut each other. The light blocking member may overlap the thin film transistor. The supporting member may be formed to overlap the light blocking member.

### BRIEF DESCRIPTION OF THE DRAWINGS

FIG. 1 shows a plan view illustrating a pixel of a display device (e.g., a liquid crystal display device) according to an embodiment of the present invention.

FIG. 2 shows a schematic cross-sectional view taken along a line II-II indicated in FIG. 1.

FIG. 3 shows a schematic cross-sectional view taken along a line III-III indicated in FIG. 1.

FIG. 4 shows a schematic cross-sectional view of a structure formed in a process of manufacturing a display device according to an embodiment of the present invention.

FIG. 5 shows a schematic cross-sectional view of a structure formed in a process of manufacturing a display device according to an embodiment of the present invention.

FIG. 6 shows a schematic cross-sectional view of a structure formed in a process of manufacturing a display device according to an embodiment of the present invention.

FIG. 7 shows a schematic cross-sectional view of a structure formed in a process of manufacturing a display device according to an embodiment of the present invention.

FIG. 8 shows a schematic cross-sectional view of a structure formed in a process of manufacturing a display device according to an embodiment of the present invention.

FIG. 9 shows a schematic cross-sectional view of a structure formed in a process of manufacturing a display device according to an embodiment of the present invention.

FIG. 10 shows a schematic cross-sectional view of a structure formed in a process of manufacturing a display device according to an embodiment of the present invention.

FIG. 11 shows a schematic cross-sectional view of a structure formed in a process of manufacturing a display device according to an embodiment of the present invention.

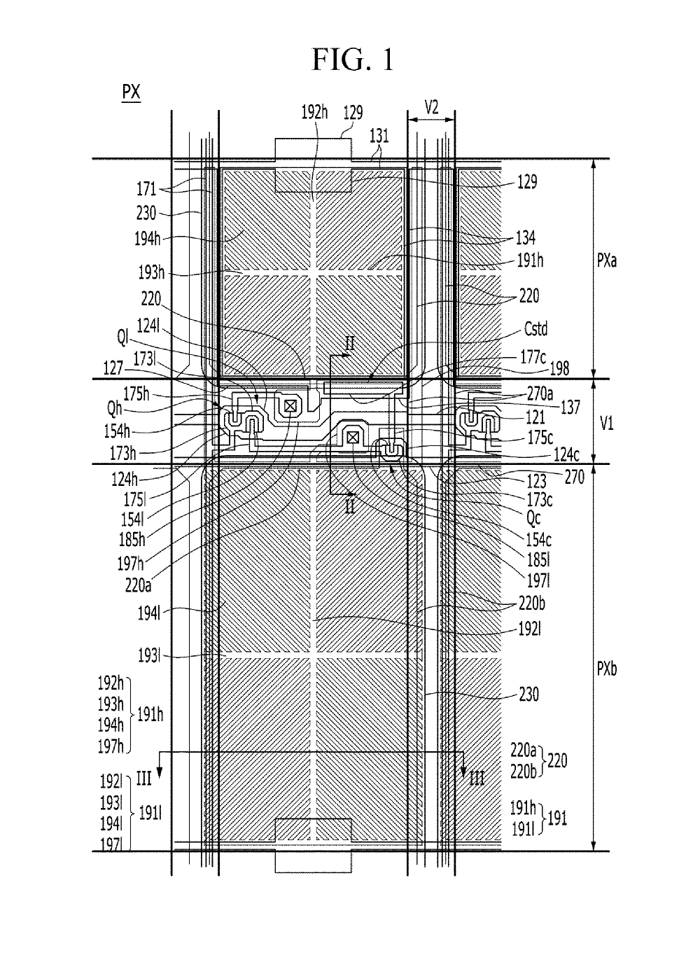

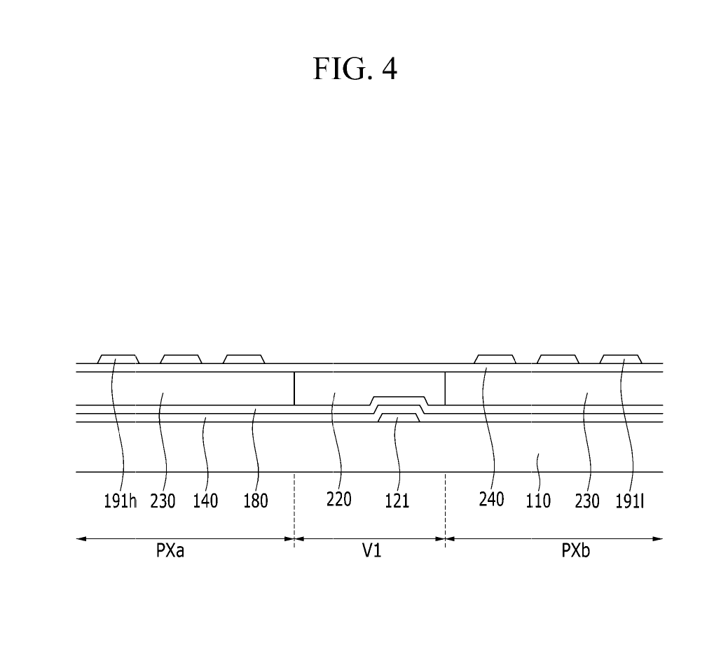

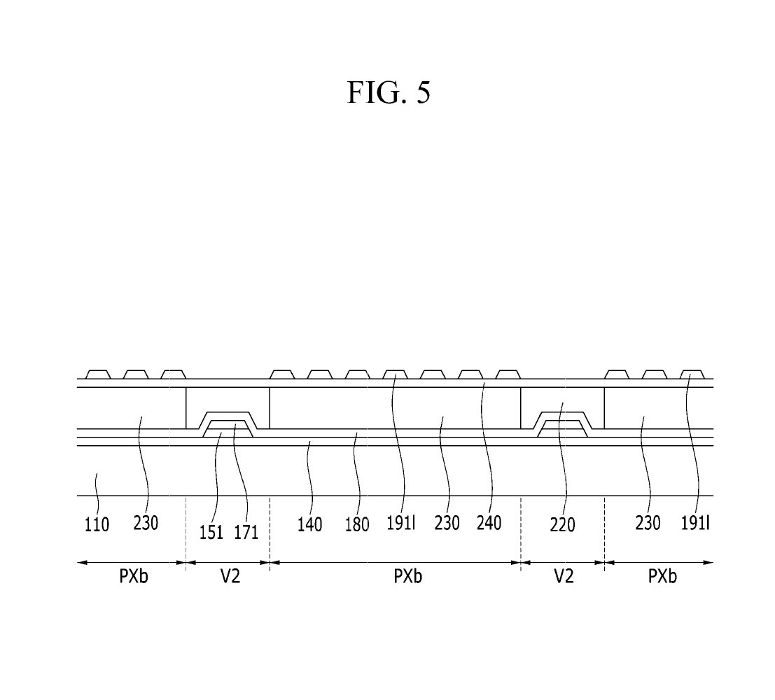

FIGS. 4, 6, 8, and 10 show schematic cross-sectional views taken along lines analogous to the II-II indicated in FIG. 1. FIGS. 5, 7, 9, and 11 show schematic cross-sectional views taken along lines analogous to the line III-III indicated in FIG. 1.

### DETAILED DESCRIPTION OF EMBODIMENTS

Embodiments of the present invention are described with reference to the accompanying drawings. As those skilled in the art would realize, the described embodiments may be modified in various different ways, all without departing from the spirit or scope of the present invention.

Although the terms “first”, “second”, etc. may be used herein to describe various elements, these elements, should not be limited by these terms. These terms may be used to distinguish one element from another element. Thus, a first element discussed below may be termed a second element without departing from the teachings of the present invention. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the drawings, thicknesses of layers, films, panels, regions, etc., may be exaggerated for clarity. Like reference numerals may designate like elements in the specification. When a first element (such as a layer, film, region, or substrate) is referred to as being “on” a second element, the first element can be directly on the second element, or one or more intervening elements may also be present. In contrast, when a first element is referred to as being “directly on” a second element, there are no intervening intended elements between the first element and the second element.

In the description, the term “connect” may mean “electrically connect”; the term “insulate” may mean “electrically insulate”.

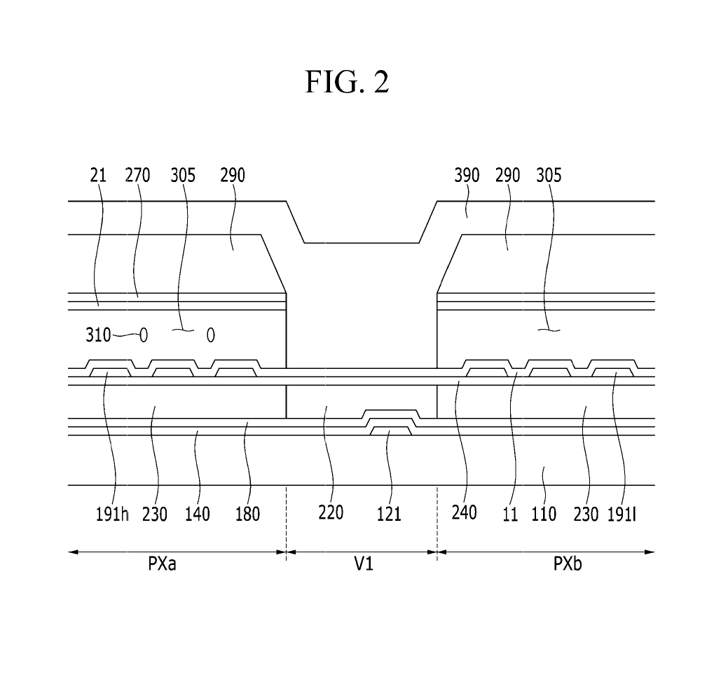

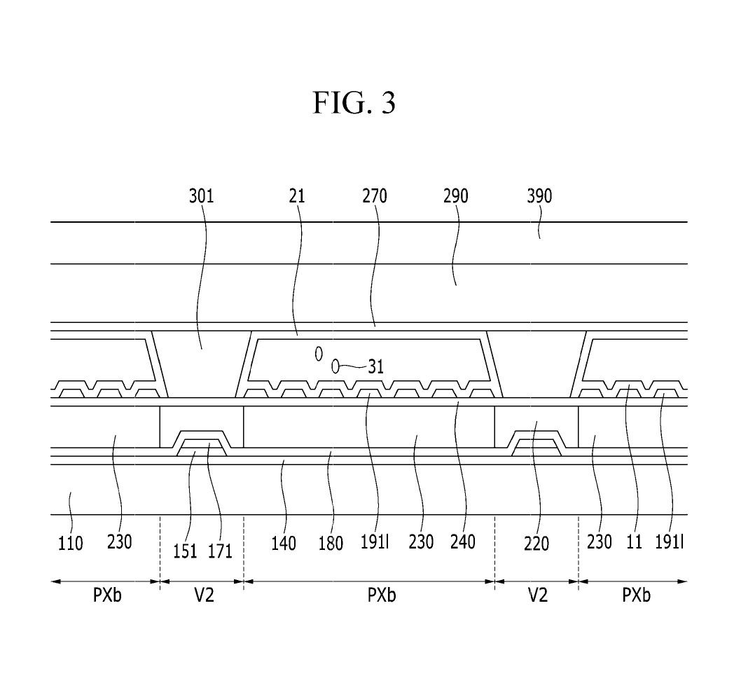

A display device, e.g., a liquid crystal display, according to an embodiment of the present invention is described with reference to FIGS. 1 to 3. FIG. 1 shows a plan view of illustrating a pixel of the display device according to an embodiment of the present invention. FIG. 2 shows a schematic cross-sectional view taken along a line II-II indicated in FIG. 1. FIG. 3 shows a schematic cross-sectional view taken along a line III-III indicated in FIG. 1.

The display device may include an insulation substrate 110, which may be made of a material such as glass or plastic. The display device may include an inorganic layer 290 that overlap the insulation substrate 110.

The display device may include a plurality of pixels PX. Each pixel may include a pixel electrode and a thin film transistor formed on a portion of the substrate 110. The pixels PX may be arranged in a matrix form (or array), which includes a plurality of pixel rows and a plurality of pixel columns. Each pixel PX may include a first-type subpixel PXa (or first subpixel PXa) and a second-type subpixel PXb (or second subpixel PXb). The first subpixel PXa and the second subpixel PXb of a pixel may be substantially aligned in a pixel column direction parallel to an extending direction of a data line.

A first-type valley V1 (or first valley V1) is positioned between a row of first subpixels PXa and a row of second subpixel PXb and may extend substantially parallel to a gate line. A second-type valley V2 (or second valley V2) may be positioned between two pixel columns. The extending direction of the gate line and the extending direction of the data line may be orthogonal to each other.

The inorganic layer 290 may have openings corresponding to the first valleys V1.

The display device may have a liquid crystal layers positioned inside cavities 305 that are formed between portions of the inorganic layer 290 and the substrate 110.

In an embodiment, the pixel PX, the first valley V1, and/or the second valley V2 may have a configuration different from the configuration discussed above. For example, a plurality of portions of the inorganic layer 290 may be connected to each other in the first valley V1.

Referring to FIGS. 1 to 3, the pixel may be associated with a plurality of gate conductors, including a gate line 121, a step-down gate line 123, and a storage electrode line 131, which may be formed on the substrate 110.

The gate line 121 and the step-down gate line 123 may mainly extend in a horizontal direction (or pixel row direction parallel to a first valley V1) and may transfer gate signals. The gate conductors may include a first gate electrode 124h and a second gate electrode 124l that protrude substantially upward and downward, respectively, from the gate line 121. The gate conductors may include a third gate electrode 124c that protrudes upward from the step-down gate line 123. The first gate electrode 124h and the second gate electrode 124l are connected to and substantially aligned with each other in the pixel column direction and may form an enlarged portion of the gate line 121. The gate electrodes 124h, 124l, and 124c may have one or more other protrusion configurations.

The storage electrode line 131 mainly extends in a horizontal direction (e.g., the pixel row direction) and may transfer a predetermined voltage, such as a common voltage Vcom. The storage electrode line 131 includes storage electrodes 129 that protrude upward and downward, a pair of vertical portions 134 that extends toward the gate line 121 and extends substantially vertical to the gate line 121, and a horizontal portion 127 that connects ends of the vertical portions 134. The horizontal portion 127 includes a capacitor electrode 137 that expands toward the gate line 121.

A gate insulating layer 140 is formed on (and may cover) the gate conductors 121, 123, 124h, 124l, 124c, and 131. The gate insulating layer 140 may be made of an inorganic insulating material, such as at least one of silicon nitride (SiNₓ) and silicon oxide (SiOₓ). The gate insulating layer 140 may have a single layer structure or a multiple layer structure.

A first semiconductor 154h, a second semiconductor 154l, and a third semiconductor 154c are formed on the gate insulating layer 140. The first semiconductor 154h may be positioned on the first gate electrode 124h, the second semiconductor 154l may be positioned on the second gate electrode 124l, and the third semiconductor 154c may be positioned on the third gate electrode 124c. The first semiconductor 154h and the second semiconductor 154l may be connected to each other, and the second semiconductor 154l and the third semiconductor 154c may be connected to each other. The first semiconductor 154h may be further formed under the data line 171. The semiconductors 154h, 154l, and 154c may be made of one or more of amorphous silicon, polycrystalline silicon, metal oxide, etc.

Ohmic contacts (not illustrated) may be formed on the semiconductors 154h, 154l, and 154c, respectively. The ohmic contacts may be made of silicide or a material (such as n+ hydrogenated amorphous silicon) in which an n-type impurity is doped at high concentration.

The pixel may be associated with a plurality of data conductors, including a data line 171, a first source electrode 173h, a second source electrode 173l, a third source electrode 173c, a first drain electrode 175h, a second drain electrode 175l, and a third drain electrode 175c. Some of the data conductors may be formed on the semiconductors 154h, 154l, and 154c.

The data line 171 may transfer a data signal. The data line 171 may mainly extend in a vertical direction (e.g., the pixel column direction) and may cross the gate line 121 and the step-down gate line 123. The data line 171 may include (or may be connected to) a first source electrode 173h and a second source electrode 173l, which extend toward (and/or correspond to) the first gate electrode 124h and the second gate electrode 124l, respectively, and are connected with each other.

Each of a first drain electrode 175h, a second drain electrode 175l, and a third drain electrode 175c may include a relatively wide portion and a relatively narrow rod-shaped portion. The rod-shaped portions of the first drain electrode 175h and the second drain electrode 175l are partially surrounded by the first source electrode 173h and the second source electrode 173l, respectively. The relatively wide portion of the second drain electrode 175l is connected to a third source electrode 173c, which has a ‘U’-lettered shape. The relatively wide portion 177c of the third drain electrode 175c overlaps the capacitor electrode 137 to form a step-down capacitor Cstd, and the rod-shaped portion of the third drain electrode 175c is partially surrounded by the third source electrode 173c.

The first gate electrode 124h, the first source electrode 173h, and the first drain electrode 175h form a first thin film transistor Qh together with the first semiconductor 154h. The second gate electrode 124l, the second source electrode 173l, and the second drain electrode 175l form a second thin film transistor Ql together with the second semiconductor 154l. The third gate electrode 124c, the third source electrode 173c, and the third drain electrode 175c form a third thin film transistor Qc together with the third semiconductor 154c.

The first semiconductor 154h, the second semiconductor 154l, and the third semiconductor 154c are connected to each other. One or more of the semiconductors 154h, 154l, and 154c may have substantially the same planar shape as one or more of the data conductors 173h, 173l, 173c, 175h, 175l, and 175c and/or one or more of the associated ohmic contacts, except for one or more channel regions between one or more of the source electrodes 173h, 173l, and 173c and one or more of the drain electrodes 175h, 173l, and 175c.

In the first semiconductor 154h, an exposed portion that is not covered by the first source electrode 173h and the first drain electrode 175h is disposed between the first source electrode 173h and the first drain electrode 175h in a plan view of the display device. In the second semiconductor 154l, an exposed portion which is not covered by the second source electrode 173l and the second drain electrode 175l is disposed between the second source electrode 173l and the second drain electrode 175l in a plan view of the display device. In the third semiconductor 154c, an exposed portion that is not covered by the third source electrode 173c and the third drain electrode 175c is disposed between the third source electrode 173c and the third drain electrode 175c.

A first passivation layer 180 is formed on the data conductors 171, 173h, 173l, 173c, 175h, 175l, and 175c and portions of the semiconductors 154h, 154l, and 154c exposed between the respective source electrodes 173h, 173l, and 173c and the respective drain electrodes 175h, 175l, and 175c. The first passivation layer 180 may be made of an organic insulating material or an inorganic insulating material. The first passivation layer 180 may have a single layer structure or a multiple layer structure.

A color filter 230 in each pixel area PX is formed on the first passivation layer 180. The color filter 230 may display one of primary colors and/or may display white. In an embodiment, the primary colors may be three primary colors of red, green and blue. In an embodiment, the primary colors may include cyan, magenta, and yellow. In an embodiment, a color filter 230 may extend in a column direction along a space between immediately adjacent data lines 171.

A light blocking member 220 is formed in a region between immediately adjacent color filters 230 and/or between separated portions of color filters. The light blocking member 220 overlaps at least a boundary of the pixel area PX and the thin film transistors to prevent light leakage. A color filter 230 (or a portion of a color filter 230) is formed in each of the first subpixel area PXa and the second subpixel area PXb. A portion of the light blocking member 220 may be formed between the first subpixel area PXa and the second subpixel area PXb to cover the thin film transistors.

The light blocking member 220 includes a horizontal light blocking member 220a that extends along the gate line 121 and the step-down gate line 121 and covers the first thin film transistor Qh, the second thin film transistor Ql, and the third thin film transistor Qc. The light blocking member 220 further includes a vertical light blocking member 220b that extends along the data line 171. The horizontal light blocking member 220a may overlap a first valley V1, and the vertical light blocking member 220b may overlap a second valley V2. The color filter 230 and the light blocking member 220 may directly contact each other in a same layer of the display device and may both directly contact the first passivation layer 180.

A second passivation layer 240 may be formed on the color filter 230 and the light blocking member 220. The second passivation layer 240 may be made of an inorganic insulating material, such as at least one of silicon nitride (SiNₓ) and silicon oxide (SiOₓ). The second passivation layer 240 serves to protect the color filter 230 (which may be made of an organic material) and the light blocking member 220. In an embodiment, the second passivation layer 240 may be omitted.

In the second passivation layer 240, the light blocking member 220, and the first passivation layer 180, a first contact hole 185h and a second contact hole 185l are formed.

A pixel electrode 191 is formed on the second passivation layer 240. The pixel electrode 191 may be made of a transparent metal material, such as at least one of indium tin oxide (ITO) and indium zinc oxide (IZO). The pixel electrode 191 may be connected to drain electrodes through the contact holes 185h and 185l.

The pixel electrode 191 includes a first-type subpixel electrode 191h (or first subpixel electrode 191h, for conciseness) and a second-type subpixel electrode 191l(or second subpixel electrode 191l), which are separated from each other with the gate line 121 and the step-down gate line 123 being disposed substantially between the subpixel electrodes 191h and 191l. The subpixel electrodes 191h and 191l may be substantially aligned each other in a column direction. The first subpixel electrode 191h and the second subpixel electrode 191l may be separated from each other with the first valley V1 being disposed between the subpixel electrodes in a plan view of the display device. The first subpixel electrode 191h is positioned in the first subpixel area PXa, and the second subpixel electrode 191l is positioned in the second subpixel area PXb.

The first subpixel electrode 191h and the second subpixel electrode 191l are connected to the first drain electrode 175h and the second drain electrode 175l through the first contact hole 185h and the second contact hole 185l, respectively. Accordingly, when the first thin film transistor Qh and the second thin film transistor Ql are turned on, the first subpixel electrode 191h and the second subpixel electrode 191l receive data voltages from the first drain electrode 175h and the second drain electrode 175l.

An overall shape of the first subpixel electrode 191h and the second subpixel electrode 191l may be substantially a quadrangle. The first subpixel electrode 191h and the second subpixel electrode 191l include cross stems. The cross stems include horizontal 193h and 193l and vertical stems 192h and 192l that cross the horizontal stems 193h and 193l, respectively. The first subpixel electrode 191h and the second subpixel electrode 191l may include a plurality of minute branches 194h and 194l and may include protrusions 197h and 197l protruding downward or upward from edge sides of the subpixel electrodes 194h and 194l, respectively.

Each of the subpixel electrodes 191h and 191l of the pixel electrode 191 is divided into four sub-regions by an associated one of the horizontal stems 193h and 193l and an associated one of the vertical stems 192h and 192l. The minute branches 194h and 194l obliquely extend from the horizontal stems 193h and 193l and the vertical stems 192h and 192l, extending at an angle of approximately 45 degrees or 135 degrees with respect to the gate line 121 or the horizontal stems 193h and 193l. In an embodiment, directions in which the minute branches 194h and 194l of the two adjacent sub-regions extend may be perpendicular to each other.

In an embodiment, the first subpixel electrode 191h may include an outer stem that surrounds at least some elements of the first subpixel electrode 191h. The second subpixel electrode 191l may include horizontal portions positioned at an upper end and a lower end of the second subpixel electrode 191l. The pixel electrode 191 may include left and right vertical portions 198 positioned at the left and the right of the first subpixel electrode 191h. The left and right vertical portions 198 may prevent capacitive coupling between the data line 171 and the first subpixel electrode 191h.

The layout shape of the pixel area, the structure of the thin film transistor, and the shape of the pixel electrode described above are examples and may be modified in various embodiments.

A common electrode 270 may overlap the pixel electrode 191 and may be spaced from the pixel electrode 191 at a predetermined distance. A cavity 305 may be formed between the pixel electrode 191 and the common electrode 270 and between two supporting members. That is, the cavity 305 is surrounded by the pixel electrode 191, the common electrode 270, and the two supporting members 301. A width and an area of the cavity 305 may be configured according to a size and a resolution of the display device.

A supporting member 301 may be positioned between two adjacent pixels PX, may extend parallel to a data line 171, and may overlap the data line 171. Supporting members 301 may formed at positions corresponding to the second valleys V2 and the vertical light blocking members 220.

Each supporting member 301 may be positioned between liquid crystal layers of two adjacent pixels and may support the common electrode 270 and the inorganic layer 290.

Referring to FIG. 3, a cross-section of the cavity 305 that is parallel to an extension direction of a gate line 121 may have a substantially trapezoid shape that has a narrower (and smaller) upper side positioned closer to the common electrode 270. A cross section of a supporting member 301 that is parallel to the extension direction of the gate line 121 may have a substantially trapezoid shape that has a wider (and larger) upper side directly contacting the common electrode 270 and has an acute-angled corner portion positioned between the pixel electrode 191 and the common electrode 270 in a direction perpendicular to the common electrode 270. The upper side of the supporting member 301 may be sufficiently wide (e.g., wider than the light blocking member 220) and may additionally prevent light leakage. The lower side of the supporting member 301 may be sufficiently narrow (e.g., narrower than the light blocking member 220), such that the pixel electrode 191 may have sufficient coverage.

The pixel electrode 270 may be made of a transparent metal material such as at least one of indium tin oxide (ITO) and indium zinc oxide (IZO). A predetermined voltage may be applied to the common electrode 270, and an electric field may be generated between the pixel electrode 191 and the common electrode 270.

A first-type alignment layer 11 (or first alignment layer 11) is formed on the pixel electrode 191. The first alignment layer 11 may also be formed directly on a portion of the second passivation layer 240 that is not covered by the pixel electrode 191.

A second-type alignment layer 21 (or second alignment layer 21, for conciseness) is formed on the common electrode 270. The second alignment layer 21 is disposed between the common electrode 270 and the first alignment layer 11.

The first alignment layer 11 and the second alignment layer 21 may be vertical alignment layers and may be made of alignment materials, such as at least one of polyamic acid, polysiloxane, and polyimide. The alignment layers 11 and 21 may be connected to each other at an edge of the pixel area PX.

A liquid crystal layer may include liquid crystal molecules 310 and may be formed in the cavity 305 positioned between the pixel electrode 191 and the common electrode 270. The liquid crystal molecules 310 may have negative dielectric anisotropy and may be oriented in a vertical direction that is substantially perpendicular to the substrate 110 when no electric field is applied to the pixel electrode 191.

The first subpixel electrode 191h and the second subpixel electrode 191l to which the data voltage is applied generate an electric field together with a common electrode 270 to determine directions of the liquid crystal molecules 310. The luminance of light that is transmitted through the liquid crystal layer may be substantially determined by the directions (or orientations) of the liquid crystal molecules 310.

The inorganic layer 290 is positioned on the common electrode 270. The inorganic layer 290 may be made of an inorganic material such as SiNₓ or SiOₓ. The inorganic layer 290 may have a substantially uniform thickness and may have a maximum thickness of about 2 μm or less in a direction perpendicular to the common electrode 270, such that the inorganic layer 290 may be satisfactorily supported by the supporting members 301.

The cavity 305 is positioned below a combination of the common electrode 270 and the inorganic layer 290. The two associated supporting members 301, the common electrode 270, and the inorganic layer 290 may maintain the shape of the cavity 305. The inorganic layer 290 may be spaced from the pixel electrode 191 by at least the cavity 305 (and the liquid crystal layer positioned inside the cavity 305).

The inorganic layer 290 may have openings corresponding to the first valleys V1, or regions between the first subpixel PXa and the second subpixel PXb and between the adjacent pixels, for facilitating formation of the common electrode 270, the cavities 305, the liquid crystal layers, and the alignment layers. A cavity 305 is positioned below a portion of the inorganic layer 290 in each of the first subpixels PXa and the second subpixels PXb. In each second valley V2, a supporting member 301 may be positioned below the inorganic layer 290 and may support the inorganic layer 290. An upper side of a cavity 305 is covered by the inorganic layer 290, and two lateral sides of the cavity 305 are blocked by the supporting member 301.

If the two sides of the cavity 305 are covered by an inorganic layer 290, the cavity 305 may have a protruding portion, and liquid crystal molecules may not be able to smoothly move into the protruding portion, such that the protruding portion may not be sufficiently filled. As a result, structural robustness and/or image display quality associated with the pixel (and the display device) may be affected.

Inorganic layers 290 may not overlap first valley regions. A first valley region may be positioned between two inorganic layers 290 in the layout view of the display device. Side surfaces of inorganic layers 290 positioned at two sides of a first valley region may be inclined for facilitating supply of liquid crystal material through the first valley region.

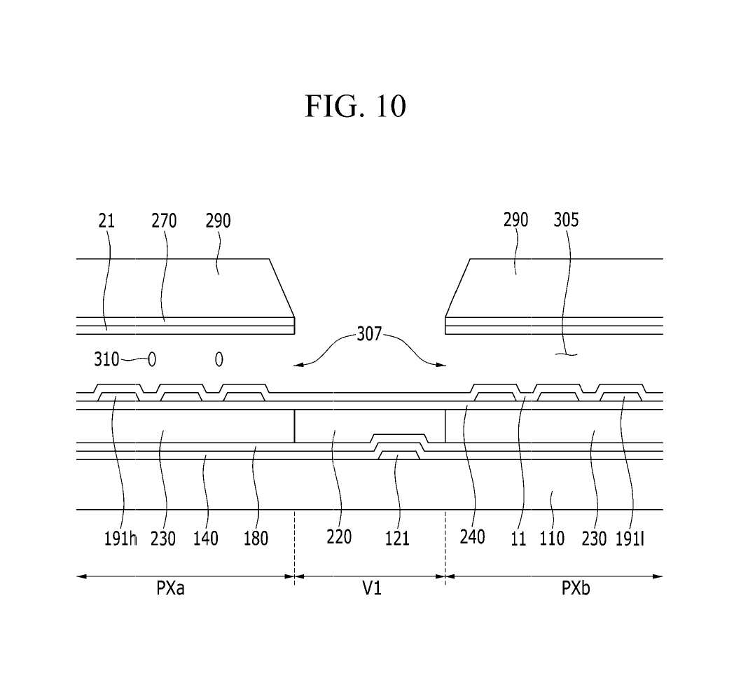

An overcoat 390 is positioned on the inorganic layer 290. The overcoat 390 may seal the openings of the inorganic layer 290 (and injection holes 307 illustrated in FIG. 10). That is, the overcoat 390 may seal the cavities 305 so that the liquid crystal molecules 310 formed in the cavities 305 may not be leaked. Since the overcoat 390 may contact the liquid crystal molecules 310, the overcoat 390 may be made of a material which does not substantially react with liquid crystal molecules 310.

The overcoat 390 may have a multilayer structure, such as a double layer structure or a triple layer structure. The double layer structure may include two layers made of different materials. In the triple layer structure, materials of adjacent layers are different from each other. In an embodiment, the overcoat 390 may include a layer made of an organic insulating material and a layer made of an inorganic insulating material.

Although not illustrated, polarizers may be further formed on upper and lower surfaces of the display device. The polarizers may include a first polarizer and a second polarizer. The first polarizer may be attached onto the lower surface of the substrate 110, and the second polarizer may be attached onto the overcoat 390.

According to embodiments of the present invention, the common electrode 270 and the pixel electrode 191 may keep a substantially uniform separation, such that a substantially uniform electric field may be formed. As a result, the alignment of the liquid crystal molecules 310 may be substantially uniform. Advantageously, satisfactory image display quality may be attained.

According to embodiments of the present invention, the supporting members 301 may maintain consistent shapes of the cavities 305, such that the shapes of the liquid crystal layers may be substantially consistent. Advantageously, satisfactory image display quality may be attained.

A method for manufacturing the display device according to an embodiment of the present invention is described with reference to FIGS. 1 to 11. FIGS. 4, 6, 8, and 10 are schematic cross-sectional taken along lines analogous to the line II-II indicated in FIG. 1. FIGS. 5, 7, 9, and 11 are schematic cross-sectional views taken along lines analogous to the line III-III indicated in FIG. 1.

Referring to at least FIG. 1, FIG. 4, and FIG. 5, on the insulation substrate 110 made of glass or plastic, a gate line 121 and a step-down gate line 123 extending in one direction, and the first gate electrode 124h, the second gate electrode 124l, and the third gate electrode 124c which protrude from the gate line 121 are formed.

The storage electrode line 131 may be formed in the same process stem and be spaced from the gate line 121, the step-down gate line 123, and the first to third gate electrodes 124h, 124l, and 124c.

Subsequently, the gate insulating layer 140 is formed on the gate line 121, the step-down gate line 123, the first to third gate electrodes 124h, 124l, and 124c, and the storage electrode line 131. The gate insulating layer 140 may be formed of an inorganic insulating material, such as silicon oxide (SiOx) or silicon nitride (SiNx). The gate insulating layer 140 may have a single layer or multiple layers.

Subsequently, the first semiconductor layer 154h, the second semiconductor layer 154l, and the third semiconductor layer 154c are formed by depositing and then patterning a semiconductor material, such as at least one of amorphous silicon, polycrystalline silicon, and metal oxide, on the gate insulating layer 140. The first semiconductor layer 154h may be positioned on the first gate electrode 124h, the second semiconductor layer 154l may be positioned on the second gate electrode 124l, and the third semiconductor layer 154c may be positioned on the third gate electrode 124c.

Subsequently, the data line 171 is formed by depositing and then patterning a metal material. The metal material may have a single layer or multiple layers.

The first source electrode 173h protruding above the first gate electrode 124h from the data line 171, and the first drain electrode 175h spaced apart from the first source electrode 173h may be formed in the same process step. The second source electrode 173l connected with the first source electrode 173h, and the second drain electrode 175l spaced apart from the second source electrode 173l may be formed in the same process step. The third source electrode 173c extended from the second drain electrode 175l, and the third drain electrode 175c spaced apart from the third source electrode 173c may be formed in the same process step.

The semiconductor layers 154h, 154l, and 154c, the data line 171, the source electrodes 173h, 173l, and 173c, and the drain electrodes 175h, 175l, and 175c may be formed by sequentially depositing and simultaneously patterning a semiconductor material and a metal material. The first semiconductor layer 154h may extend to overlap the data line 171.

The gate electrodes 124h, 124l, and 124c, the source electrodes 173h, 173l, and 173c, and the drain electrodes 175h, 175l, and 175c may form thin film transistors (TFTs) Qh, Ql, and Qc with the semiconductor layers 154h, 154l, and 154c, respectively.

Subsequently, the first passivation layer 180 may be formed on the gate insulating layer 140. The first passivation layer 180 may be made of an organic insulating material or an inorganic insulating material, and may have a single-layer structure or a multilayer structure.

Subsequently, a color filter 230 may be formed in each pixel area PX on the first passivation layer 180. Color filters 230 may be formed in the first subpixels PXa and the second subpixels PXb, and may not be formed in the first valley V1. Color filters 230 having the same color may be arranged in a direction parallel to a. In an embodiment, for forming color filters 230 having three colors, a first color filter 230 may be first formed, subsequently a second color filter 230 may be formed by shifting a mask, and subsequently a third color filter may be formed by shifting the mask.

Subsequently, the light blocking member 220 may be formed boundaries (or valleys V2) between pixels PX and boundaries (or valleys V1) between subpixels PXa and PXb on the first passivation layer 180 and the thin film transistor. The light blocking member 220 may abut neighboring color filters 230 and may minimize or substantially prevent light leakage.

Subsequently, the second passivation layer 240, made of an inorganic insulating material such as at least one of silicon nitride (SiNx), silicon oxide (SiOx), and silicon oxynitride (SiOₓN_{y}), may be formed on the color filter 230 and the light blocking member 220.

The color filters 230, the light blocking member 220, and the second passivation layer 240 may be formed according to various sequences (or orders) in various embodiments.

Subsequently, by etching the first passivation layer 180, the light blocking member 220, and the second passivation layer 240, a first contact hole 185h may be formed so as to expose a part of the first drain electrode 175h, and a second contact hole 185l may be formed so as to expose a part of the second drain electrode 175l.

Subsequently, by depositing and then patterning a transparent metal material such as indium tin oxide (ITO) and indium zinc oxide (IZO) on the second passivation layer 240, the first subpixel electrode 191h may be formed in the first subpixel PXa, and the second subpixel electrode 191l may be formed in second subpixel PXb. The first subpixel electrode 191h and the second subpixel electrode 191l may be separated from each other by at least the first valley V1. The first subpixel electrode 191h may be connected to the first drain electrode 175h through the first contact hole 185h, and the second subpixel electrode 191l may be connected to the second drain electrode 175l through the second contact hole 185l.

The horizontal stems 193h and 193l and the vertical stems 192h and 192l may be formed in the first subpixel electrode 191h and the second subpixel electrode 191l. A plurality of minute branches 194h and 194l, which obliquely extend from the horizontal stems 193h and 193l and the vertical stems 192h and 192l, may be formed.

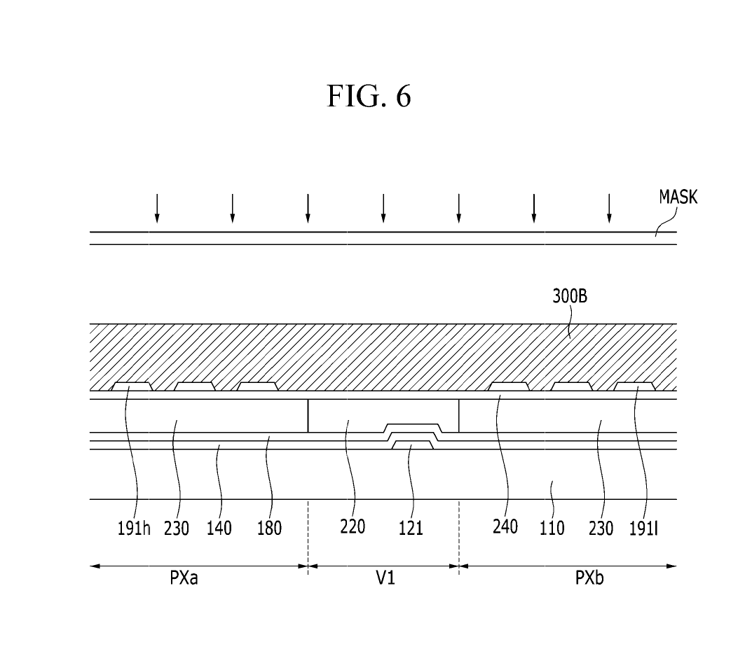

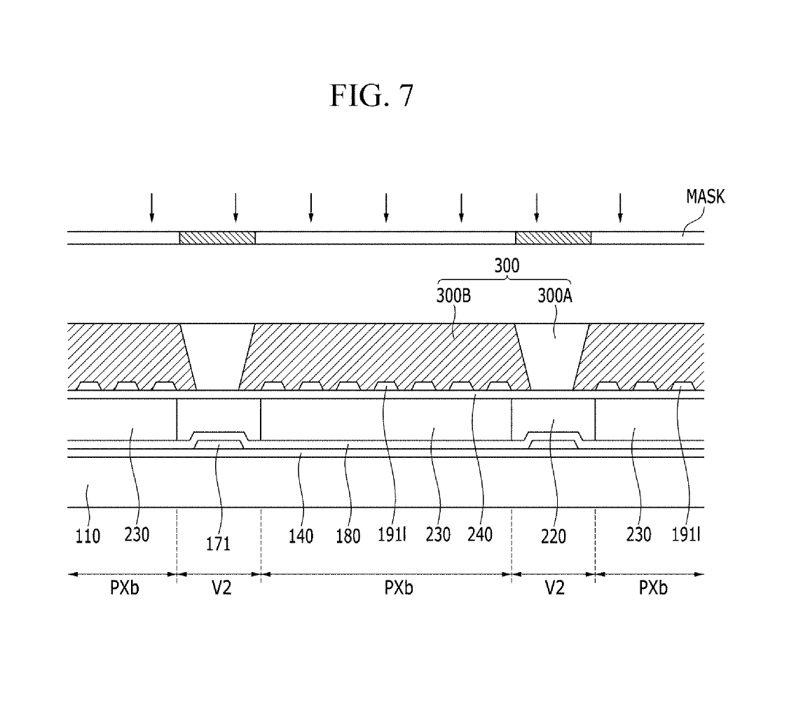

Subsequently, referring to FIGS. 6 and 7, a sacrificial layer 300 may be formed on the pixel electrode 191. The sacrificial layer 300 may be formed of a positive photoresist material.

The sacrificial layer 300 may be formed on the entire surface of the plurality of pixels PX. That is, the sacrificial layer 300 may be formed to cover each pixel PX, the first valleys V1 positioned between the first subpixels PXa and the second subpixels PXb, and the second valleys V2 positioned between the neighboring pixels PX.

Subsequently, a mask may be provided over the sacrificial layer 300. The mask may cover a sacrificial layer portion 300A, which overlaps a second valley V2, and may expose a sacrificial layer portion 300B, which overlaps at least one of a subpixel PXb and a subpixel PXa.

Thereafter, a light, such as ultraviolet rays (UV), may be irradiated on the sacrificial layer 300 through the mask. The light may not be irradiated on the blocked sacrificial layer portion, but may be irradiated on the exposed sacrificial layer portion 300B. As a result of the process, the sacrificial layer portion 300A may remain insoluble with respect to a developer, and the sacrificial layer portion 300B may become soluble with respect to the developer.

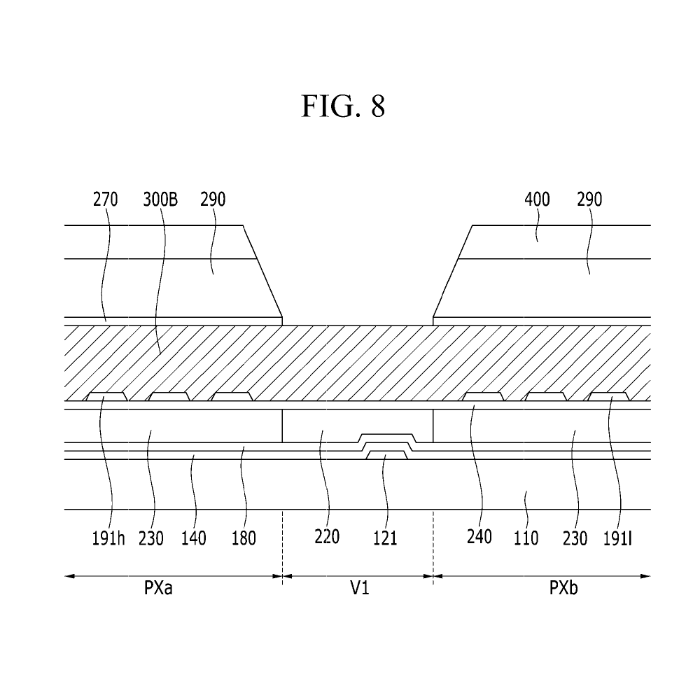

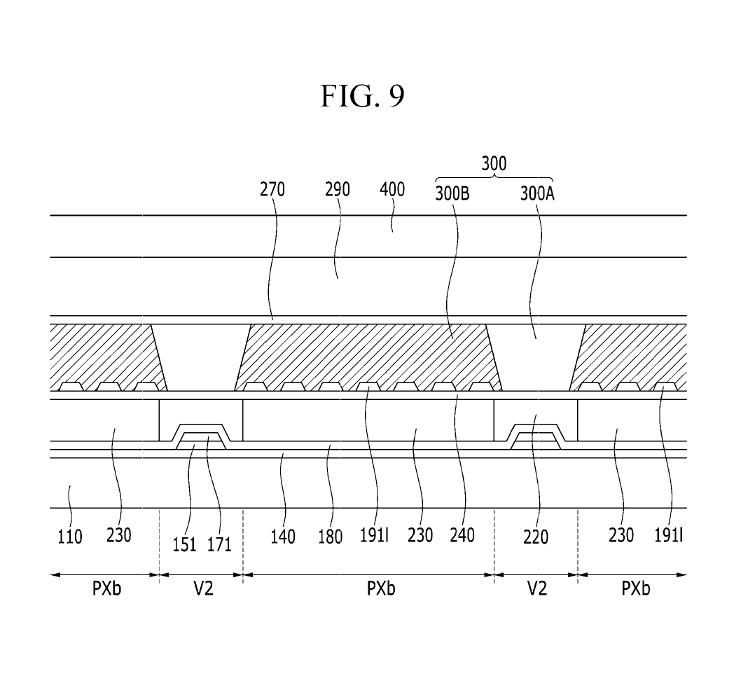

Referring to FIGS. 8 and 9, a transparent metal conductor layer, such as at least one of an indium tin oxide (ITO) layer and an indium zinc oxide (IZO) layer, may be deposited on the sacrificial layer 300. Subsequently, an inorganic material layer may be coated on the entire surface of the metal conductor layer.

Subsequently, a portion of the inorganic material layer may be removed through the mask 400 using, for example, a developing and/or etching process, to form the inorganic layer 290, which has an opening at a valley V1. The common electrode 270 may be formed by etching the metal conductor layer through the opening the inorganic layer 290. The resulted common electrode 270 has a hole at the volley V1.

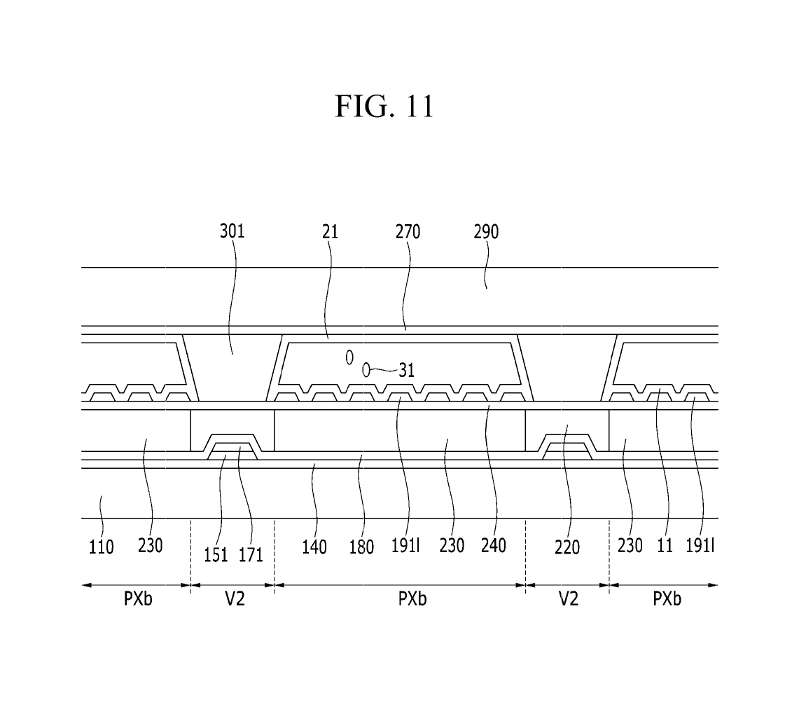

Thereafter, referring to FIGS. 10 and 11, a developer may be provided through the opening of the inorganic layer 290 and though the hole of the common electrode 270 to develop the sacrificial layer 300. As a result, the soluble sacrificial layer portion 300B may be fully removed, such that a cavity 305 may be formed. The insoluble sacrificial layer portion 300A may remain on the passivation layer 240 and may serve as a supporting member 301 that at least partially supports the common electrode 270 and the inorganic layer 290.

The pixel electrode 191 and the combination of the common electrode 270 and the inorganic layer 290 may be spaced from each other by at least the cavity 305. The upper side of the cavity 305 may be covered by the common electrode 270 and the inorganic layer 290, and two lateral sides of the cavity 305 may be blocked by two supporting members 301. The common electrode 270 and the inorganic layer 290 may be substantially flat.

The cavity 305 may be exposed through an injection hole 307, which may be accessible through the opening of the inorganic layer 290 and the hole of the common electrode 270. Injection holes 307 may be formed along first valleys V1. In an embodiment, an injection hole 307 may be formed an edge of a first subpixel PXa, and an injection hole 307 may be formed at an edge of a second subpixel PXb, wherein the edge of the subpixel PXb may be opposite the edge of the subpixel PXa. In an embodiment, injection holes 307 may be formed along second valleys V2.

Subsequently, an aligning agent (including an alignment material) may be provided, e.g., using a spin coating method or an inkjet method, into the cavity 305 through the injection hole 307. Subsequently, a curing process may be performed on the alignment agent, such that a solution component may be evaporated and that the alignment material may remain on the inner wall of the cavity 305.

Accordingly, the first alignment layer 11 may be formed on the pixel electrode 191, and the second alignment layer 21 may be formed on the common electrode 270. The first alignment layer 11 and the second alignment layer 21 be substantially spaced from each other and may have end portions connected to each other at an edge of the pixel PX.

In an embodiment, the alignment layers 11 and 21 may be configured to substantially align liquid crystal molecules in a vertical direction that is substantially perpendicular to the substrate 110 (i.e., perpendicular to a surface of the substrate 110 that overlaps the roof layer 360, except, for example, at positions where bead members 400 are located. In an embodiment, a process of irradiating UV light on the alignment layers 11 and 21 may be performed; as a result, the alignment layers 11 and 21 may be configured to substantially align liquid crystal molecules in a horizontal direction that is substantially parallel to the substrate 110.

Subsequently, liquid crystal material that includes liquid crystal molecules 310 is provided (e.g., dropped) on the substrate 110 using an inkjet method or a dispensing method. The liquid crystal material is provided (e.g., injected) into a cavity 305 through a corresponding injection hole 307. In an embodiment, liquid crystal material may be provided (e.g., dropped) through injection holes 307 formed along only one first valley V1 of two immediately neighboring first valleys V1 (e.g., one that does not correspond to support members). For example, support members may be formed along two sides of each odd numbered first valley V1, and liquid crystal material is dropped in only the even-numbered first valleys V1 without being dropped in the odd-numbered first valleys V1. As another example, support members may be formed along two sides of each even numbered first valley V1, and liquid crystal material is dropped in only the odd-numbered first valleys V1 without being dropped in the even-numbered first valleys V1.

In an embodiment, liquid crystal material is provided to the injection holes 307 formed along the odd-numbered first valleys V1, and the liquid crystal material may enter the injection hole 307 through capillary action into the cavity 305. As the liquid crystal material enters into the cavity 305, the liquid crystal material may push the air in the cavity 305 such that the air may be discharged through the injection hole 307 formed along the even-numbered first valley V1.

In an embodiment, liquid crystal material may be provided through all of the injection holes 307. In an embodiment, liquid crystal material may be provided through injection holes 307 formed along odd-numbered first valleys V1 and may be provided through injection holes 307 formed along even-numbered first valleys V1.

The overcoat layer 390 may be formed by depositing a material that does not substantially (chemically) react with the liquid crystal molecules 310 on the inorganic layer 290 and the injection hole 307. The overcoat 390 may seal the opening of the inorganic layer 290, the hole of the common electrode, and the injection hole 307. The resulted liquid crystal display device structure is illustrated in FIGS. 2 and 3.

Subsequently, although not illustrated, a first polarizer may be attached onto the lower surface of the substrate 110, and a second polarizer may be attached onto the overcoat 390.

According to embodiments of the present invention, in a display device, a common electrode and a pixel electrode may have a consistent separation, such that a consistent electric field may be formed. As a result, orientations of liquid crystal molecules of the display device may be substantially consistent. Advantageously, the display device may display images with satisfactory quality.

According to embodiments of the present invention, in a display device, supporting members may sufficiently ensure consistent shapes of cavities that contain liquid crystal layers. As a result, the shapes of the liquid crystal layers may remain substantially consistent. Advantageously, the display device may display images with satisfactory quality.

While this invention has been described in connection with what is presently considered to be practical embodiments, the invention is not limited to the described embodiments. This invention is intended to cover various modifications and equivalent arrangements included within the spirit and scope of the appended claims.

What is claimed is:

1. A display device comprising:
a first transistor, which comprises a gate electrode, a source electrode, and drain electrode;
a gate line, which is electrically connected to the gate electrode;
a data line, which is electrically connected to the source electrode;
a common electrode;
a passivation layer, which overlaps the common electrode;
a first pixel electrode, which is electrically connected to the drain electrode and is positioned between the common electrode and the passivation layer;
a first liquid crystal layer, which is positioned between the common electrode and the first pixel electrode;
a second transistor, which is electrically connected to the gate line;
a second pixel electrode, which is electrically connected to the second transistor;
a second liquid crystal layer, which is positioned between the common electrode and the second pixel electrode; and
a supporting member, which is positioned between the common electrode and the passivation layer and is positioned between the first liquid crystal layer and the second liquid crystal layer.

2. The display device of claim 1, wherein the supporting member overlaps the data line.

3. The display device of claim 1, comprising: a light blocking member, which is positioned between the supporting member and the data line.

4. The display device of claim 1, wherein the supporting member directly contacts a first side of the passivation layer, and wherein the first pixel electrode directly contacts the first side of the passivation layer.

5. The display device of claim 1, comprising: an inorganic layer, wherein a first portion of the common electrode is positioned between the inorganic layer and the liquid crystal layer, and wherein a second portion of the common electrode is positioned between the inorganic layer and the supporting member.

6. The display device of claim 1, wherein the supporting member is formed of a positive photoresist material.

7. The display device of claim 1, comprising: an inorganic directly contacting a first side of the common electrode, wherein the supporting member directly contacts a second side of the common electrode, and wherein a maximum thickness of the inorganic layer in a direction perpendicular to the common electrode is 2 μm or less.

8. The display device of claim 1, wherein a first side of the supporting member directly contacts the passivation layer, wherein a second side of the supporting member directly contacts the common electrode, and wherein the first side of the supporting member is narrower than the second side of the supporting member.

9. The display device of claim 1, comprising: an alignment directly contacting each of the common electrode, the supporting member, and the first liquid crystal layer and configured for orienting liquid crystal molecules in the first liquid crystal layer.

10. The display device of claim 1, wherein a portion of the supporting member directly contacts the common electrode and is positioned between the common electrode and the first pixel electrode in a direction perpendicular to the common electrode, and wherein the portion of the supporting member has an acute angle in a cross-sectional view of the display device.

11. A display device comprising:
a transistor, which includes a gate electrode, a source electrode, and drain electrode;
a gate line, which is electrically connected to the gate electrode;
a data line, which is electrically connected to the source electrode;
a common electrode;
a passivation layer, which overlaps the common electrode;
a pixel electrode, which is electrically connected to the drain electrode and is positioned between the common electrode and the passivation layer;
a liquid crystal layer, which is positioned between the common electrode and the pixel electrode; and
a supporting member, which is formed of a positive photoresist material and is positioned between the common electrode and the passivation layer.

12. The display device of claim 11, comprising: a light blocking member, which overlaps the supporting member in a direction perpendicular to the common electrode, wherein the passivation layer directly contacts each of the supporting member and the light blocking member.

13. The display device of claim 12, wherein a first side of the supporting member is positioned between the light blocking member and a second side of the supporting member, and wherein the first side of the supporting member is narrower than at least one of the light blocking member and the second side of the supporting member.

14. A method for manufacturing a display device, the method comprising:
forming a thin film transistor;
forming a pixel electrode that is connected to the thin film transistor;
providing a positive photoresist layer that covers the pixel electrode;
exposing a first portion of the positive photoresist layer to light when blocking a second portion of the positive photoresist layer from the light;
providing a conductor layer on the positive photoresist layer;
providing an inorganic layer that has an opening on the conductor layer;
etching the conductor layer through the opening to form a common electrode that has a hole;
providing a developer through the opening and the hole for removing the first portion of the positive photoresist layer to form a cavity, wherein the second portion of the photoresist layer remains as a supporting member;
providing a liquid crystal material through the opening and the hole into the cavity to form a liquid crystal layer; and
providing an overcoat that covers the inorganic layer and seals the opening.

15. The method of claim 14, comprising: providing a passivation layer before forming the pixel electrode, wherein the pixel electrodes is formed on the passivation layer, and wherein the supporting member directly contacts each of the common electrode and the passivation layer.

16. The method of claim 14, comprising: providing a light blocking member, wherein the supporting member overlaps the light blocking member in a direction perpendicular to the common electrode, wherein a first side of the supporting member is positioned between the light blocking member and a second side of the supporting member, and wherein the first side of the supporting member is narrower than at least one of the light blocking member and the second side of the supporting member.

17. The method of claim 15, wherein the first side of the supporting member is narrower than the light blocking member, and wherein the light blocking member is narrower than the second side of the supporting member.

18. The method of claim 14, wherein a maximum thickness of the inorganic layer in a direction perpendicular to the common electrode is 2 μm or less.

19. The method of claim 14, wherein the supporting member has a first side and a second side, wherein the second side directly contacts the common electrode, is parallel to the first side, and is wider than the first side.

20. The method of claim 14, comprising: providing an alignment material through the opening and the hole into the cavity to form an alignment layer before forming the liquid crystal layer, wherein the alignment layer directly contacts each of the common electrode and the supporting member.
